(19) United States
(12) Patent Application Publication
(10) Pub. No.: US 2026/0066008 A1
(43) Pub. Date: Mar. 5, 2026

(54) MEMORY DEVICE INCLUDING CHARGE PUMP CIRCUIT

(71) Applicant: Samsung Electronics Co., Ltd., Suwon-si (KR)

(72) Inventors: Yoon Jae LEE, Suwon-si (KR); Soo Hoon LEE, Suwon-si (KR); Je Il RYU, Suwon-si (KR)

(21) Appl. No.: 19/224,826

(22) Filed: Jun. 1, 2025

(30) Foreign Application Priority Data
Sep. 3, 2024 (KR) 10-2024-0118922

(51) Int. Cl. G11C 16/30; G11C 5/14; G11C 16/32

(52) U.S. Cl. CPC G11C 16/30; G11C 5/145; G11C 16/32

(57) ABSTRACT

A memory device may include a memory cell array including a plurality of memory cells, and a voltage generator configured to generate an output voltage and provide the output voltage to the memory cell array. The voltage generator may include a charge pump controller configured to generate a plurality of enable signals based on a clock signal, a first charge pump circuit configured to pump a first voltage and output a first pumping voltage, a second charge pump circuit configured to pump the first pumping voltage or the first voltage and output a second pumping voltage as the output voltage, and first and second switches connected between the first charge pump circuit and the second charge pump circuit. The charge pump controller is configured to respectively enable the first and second charge pump circuits in response to the plurality of enable signals.

### CROSS-REFERENCE TO RELATED APPLICATION(S)

This application claims priority under 35 U.S.C. § 119 to Korean Patent Application No. 10-2024-0118922, filed on Sep. 3, 2024 in the Korean Intellectual Property Office, the disclosure of which is incorporated by reference herein in its entirety.

### BACKGROUND

### 1. Field

The present disclosure relates to a memory device, and more specifically, to a memory device including a charge pump circuit.

### 2. Description of Related Art

Demand for a nonvolatile semiconductor memory device capable of achieving high integration and large capacity is increasing. A representative example of a nonvolatile memory device is flash memory which is currently mainly used in portable electronic devices. A relatively high voltage is required for a program operation of such a nonvolatile memory device. To this end, a voltage generator that boosts an input voltage input to the nonvolatile memory device to generate the high voltage may be provided. A charge pump circuit is a type of a DC-DC converter and may generate a voltage that is higher than the input voltage or lower than a ground voltage. The charge pump circuit may use a capacitor as an energy storage element. The charge pump circuit may include a plurality of charge pumps, and it is desirable that the number of charge pumps used can be adjusted. In general, peak current may be an important concern when using the charge pump circuit. When a magnitude of a word-line charging current is maintained in order to maintain performance of the nonvolatile memory device, the peak current may cause malfunction of the nonvolatile memory device. On the contrary, when the magnitude of the word-line charging current is reduced to prevent the peak current, a word-line setup time may increase, and the performance may deteriorate. Therefore, a scheme to prevent the performance deterioration of the nonvolatile memory device and reduce the peak current may be needed.

### SUMMARY

The present disclosure is to provide a memory device with improved performance.

According to example embodiments, a memory device incudes a memory cell array including a plurality of memory cells and a voltage generator configured to generate an output voltage and provide the output voltage to the memory cell array. The voltage generator includes a clock generator configured to generate a clock signal, a charge pump controller configured to generate a plurality of enable signals based on the clock signal, a first charge pump circuit configured to pump a first voltage and output a first pumping voltage, a second charge pump circuit configured to pump the first pumping voltage or the first voltage and output a second pumping voltage as the output voltage, and first and second switches connected between the first charge pump circuit and the second charge pump circuit. The charge pump controller is configured to respectively enable the first and second charge pump circuits in response to the plurality of enable signals. Each the plurality of enable signals is independently set an output timing from a first time-point at which the earliest enabled signal from among the plurality of enable signals is output.

According to example embodiments, a memory device incudes a memory cell array including a plurality of memory cells and a voltage generator configured to generate an output voltage and provide the output voltage to the memory cell array. The voltage generator includes a first charge pump configured to perform a first-pumping of a first voltage and output a first output voltage based on a first enable signal, a second charge pump configured to perform a second-pumping of the first output voltage and output a second output voltage based on a second enable signal, a third charge pump configured to perform a third-pumping of a second voltage and output a third output voltage based on a third enable signal, a fourth charge pump configured to perform a fourth-pumping of the third output voltage and output a fourth output voltage as the output voltage based on a fourth enable signal, a first switch connected between the second charge pump and the third charge pump, a second switch connected between the second charge pump and the fourth charge pump, and a charge pump controller configured to generate the first to fourth enable signals in response to the first and second switches being turned on or turned off. The voltage generator is configured to operate, in a first mode in which the first switch is turned on and the second switch is turned off, and in a second mode in which the first switch is turned off and the second switch is turned on. A time-point at which the second enable signal is enabled is earlier than a time-point at which the third enable signal is enabled.

According to example embodiments, a memory device incudes a memory cell array including a plurality of memory cells and a voltage generator configured to generate an output voltage and provide the output voltage to the memory cell array. The voltage generator includes a first charge pump configured to perform a first-pumping of a first voltage and output a first output voltage based on a first enable signal, a second charge pump configured to perform a second-pumping of the first output voltage based on a second enable signal, a third charge pump configured to perform a third-pumping of a second voltage and output a third output voltage based on a third enable signal, a fourth charge pump configured to perform a fourth-pumping of the third output voltage and output a fourth output voltage as the output voltage based on a fourth enable signal, a first switch connected between the second charge pump and the third charge pump, a second switch connected between the second charge pump and the fourth charge pump, and a charge pump controller configured to generate the first to fourth enable signals in response to the first and second switches being turned on or turned off. In response to the first switch being turned off and the second switch being turned on, the charge pump controller is configured to sequentially output the second enable signal and the first enable signal and to sequentially output the fourth enable signal and the third enable signal.

Specific details of other embodiments are included in the detailed description and drawings.

### BRIEF DESCRIPTION OF THE DRAWINGS

The above and other aspects and features of the present disclosure will become more apparent by describing in detail embodiments thereof with reference to the attached drawings, in which:

FIG. 1 is a block diagram illustrating a memory device according to some embodiments of the present disclosure;

FIG. 2 is a block diagram for illustrating a voltage generator of a memory device according to some embodiments of the present disclosure;

FIGS. 3A and 3B are circuit diagrams for illustrating a charge pump circuit of a memory device according to some embodiments of the present disclosure;

FIG. 4 is a diagram illustrating the charge pump of FIG. 3A according to example embodiments;

FIG. 5 is a block diagram for illustrating a charge pump controller of a memory device according to some embodiments of the present disclosure;

FIG. 6 is a diagram illustrating a stage control circuit of FIG. 5 according to example embodiments;

FIG. 7 is a block diagram for illustrating a voltage generator of a memory device according to some embodiments of the present disclosure;

FIG. 8 is a circuit diagram for illustrating a first mode of a charge pump circuit of a memory device according to some embodiments of the present disclosure;

FIG. 9 is a timing diagram for illustrating the first mode of FIG. 8 according to example embodiments;

FIG. 10 is another timing diagram for illustrating the first mode of FIG. 8 according to example embodiments;

FIG. 11 is a circuit diagram for illustrating a second mode of a charge pump circuit of a memory device according to some embodiments of the present disclosure;

FIG. 12 is a timing diagram for illustrating the second mode of FIG. 11 according to example embodiments;

FIG. 13 is another timing diagram for illustrating the second mode of FIG. 11 according to example embodiments;

FIG. 14 is a graph of output voltage versus output current of a charge pump circuit of a memory device according to some embodiments of the present disclosure;

FIG. 15 is a graph of output voltage versus efficiency of a charge pump circuit of a memory device according to some embodiments of the present disclosure; and

FIG. 16 is a block diagram of solid-state drive (SSD) system including a memory device according to some embodiments of the present disclosure.

### DETAILED DESCRIPTION

Hereinafter, the present disclosure will be described clearly and in detail to an extent that a person skilled in the art may easily practice the present disclosure using the attached drawings.

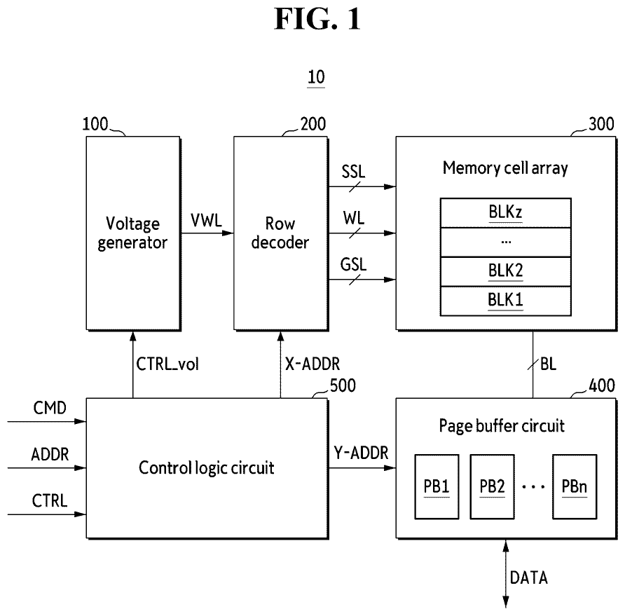

FIG. 1 is a block diagram for illustrating a memory device including a charge pump circuit according to some embodiments of the present disclosure.

A memory device 10 may be, for example, a NAND flash memory device. However, the present disclosure is not limited to the NAND flash memory device. For example, the memory device 10 may be embodied as a NAND flash memory device, a resistive random access memory (RRAM) device, a phase-change memory (PRAM) device, a magnetoresistive random access memory (MRAM) device, a ferroelectric random access memory (FRAM) device, a spin transfer torque random access memory (STT RAM), or etc. Furthermore, the memory device 10 according to the present disclosure may be implemented to have a three-dimensional array structure. For example, the memory device 10 may be a vertical NAND flash memory device having a three-dimensional array structure. The present disclosure is applicable to both a flash memory device in which a charge storage layer is composed of a conductive floating gate, and a charge trap type flash (called “CTF”) memory device in which the charge storage layer is composed of an insulating film.

Referring to FIG. 1, the memory device 10 includes a voltage generator 100, a row decoder 200, a memory cell array 300, a page buffer circuit 400, and a control logic circuit 500. Although not shown in FIG. 1, the memory device 10 may further include a data input/output circuit or an input/output interface. Furthermore, although not shown, the memory device 10 may further include various sub-circuits, such as an error correction circuit for correcting errors in data read from the memory cell array 300.

The voltage generator 100 may receive an external voltage EVC provided from an external device (e.g., a memory controller, a host, etc.). The voltage generator 100 may generate various types of internal voltages IVC for performing program, read, and erase operations on the memory cell array 300 from the external voltage EVC, based on a voltage control signal CTRL_vol. For example, the voltage generator 100 may generate a word-line voltage, a program voltage, a read voltage, a pass voltage, an erase verification voltage, or a program verification voltage. Furthermore, the voltage generator 100 may further generate a string select line voltage and a ground select line voltage based on the voltage control signal CTRL_vol. Furthermore, the voltage generator 100 may further generate a bit-line voltage based on the voltage control signal CTRL_vol.

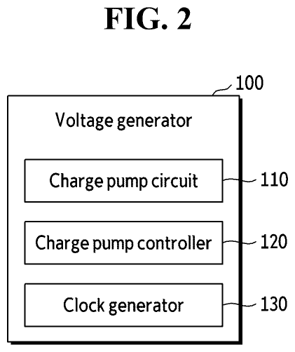

The voltage generator 100 may receive the external voltage EVC provided from the external device. The voltage generator 100 may generate a pump output voltage from the supplied external voltage EVC. The pump output voltage may include a program voltage, a read voltage, an erase voltage, a pass voltage, a bit-line voltage, and a common source line voltage. For example, the pump output voltage may be generated from a charge pump circuit 110 (shown in FIG. 2).

The row decoder 200 may select one of memory blocks BLK1 to BLKz in response to a row address X-ADDR, where z is a natural number greater than 1. The row decoder 200 may select one of word-lines WL of the selected memory block, and may select one of a plurality of string select lines SSL thereof. Furthermore, the row decoder 200 may receive a driving voltage VWL from the voltage generator 100 and transmit a voltage for performing a memory operation to the word-line of the memory block. For example, during an erase operation, the row decoder 200 may transmit an erase voltage and a verification voltage to the selected word-line, and may transmit a pass voltage to a non-selected word-line.

The memory cell array 300 may include a plurality of memory cells. For example, a plurality of memory cells included in the memory cell array 300 may be nonvolatile memory cells that maintain stored data even when the supplied power is cut off. The memory cell array 300 may be connected to string select lines SSL, word-lines WL, ground select lines GSL, and bit-lines BL. Specifically, the memory cell array 300 may be connected to the row decoder 200 via the string select lines SSL, the word-lines WL, and the ground select lines GSL, and may be connected to the page buffer circuit 400 via the bit-lines BL.

The memory cell array 300 may include a plurality of memory blocks BLK1 to BLKz, and each memory block may have a planar structure or a three-dimensional structure. The memory cell array 300 may include at least one of a single-level cell block including single-level cells (SLC), a multi-level cell block including multi-level cells (MLC), a triple-level cell block including triple-level cells (TLC), and a quad-level cell block including quad-level cells (QLC). For example, some of the memory blocks BLK1 to BLKz may be single-level cell blocks, and the other memory blocks thereof may be multi-level cell blocks, triple-level cell blocks, or quad-level cell blocks.

The page buffer circuit 400 may transmit and receive data DATA to and from an external element to the memory device 10. The page buffer circuit 400 may select some of bit-lines BL in response to a column address Y-ADDR. The page buffer circuit 400 may operate as a write driver or a sense amplifier.

The page buffer circuit 400 may be connected to the memory cell array 300 via the bit-lines BL. The page buffer circuit 400 may provide the same voltage to the bit-lines BL during an erase operation. For example, the page buffer circuit 140 may apply a program voltage to the bit-line BL to program memory cells connected to the bit-line BL to which the program voltage is applied during a program operation.

The control logic circuit 500 may output various control signals, for example, the voltage control signal CTRL_vol, the row address X-ADDR, and the column address Y-ADDR, to program the data DATA to the memory cell array 300, read the data DATA from the memory cell array 300, or erase the data DATA stored in the memory cell array 300, based on a command CMD, an address ADDR, and a control signal CTRL. For example, the control logic circuit 500 may receive the command CMD, the address ADDR, and the control signal CTRL from a memory controller external to the memory device 10. Therefore, the control logic circuit 500 may control all of various operations within the memory device 10.

FIG. 2 is a block diagram for illustrating a voltage generator of a memory device according to some embodiments of the present disclosure.

Referring to FIG. 2, the voltage generator 100 may include a charge pump circuit 110, a charge pump controller 120, and a clock generator 130. In this drawing, the clock generator 130 is illustrated as being included in the voltage generator 100. However, the present disclosure is not limited thereto. For example, the clock generator 130 may be included in the control logic circuit 500.

The charge pump circuit 110 may receive an external voltage EVC provided from an external device. The charge pump circuit 110 may generate the pump output voltage from the supplied external voltage EVC. The driving voltage VWL required for an operation of the nonvolatile memory device 10 and generated using the supplied external voltage EVC may include the pump output voltage PVOUT generated from the charge pump circuit 110. The driving voltage VWL may include, for example, the program voltage, the read voltage, the erase voltage, the pass voltage, the bit-line voltage, and the common source line voltage. However, the present disclosure is not limited thereto.

The charge pump circuit 110 may include a plurality of charge pumps, each charge pump receiving the external voltage EVC. In this regard, the number of charge pumps receiving the external voltage EVC among the plurality of charge pumps may vary depending on a stage. For example, in a first stage, one charge pump may receive the external voltage EVC, and in the second stage, two charge pumps may receive the external voltage EVC.

The charge pump controller 120 may control the stage of the charge pump circuit 110 based on a magnitude of a pump current generated in the charge pump circuit 110. However, although the charge pump controller 120 is illustrated as being included in the voltage generator 100 in this drawing, the memory device 10 according to the present disclosure is not limited thereto. For example, the charge pump controller 120 may be included in the control logic circuit 500.

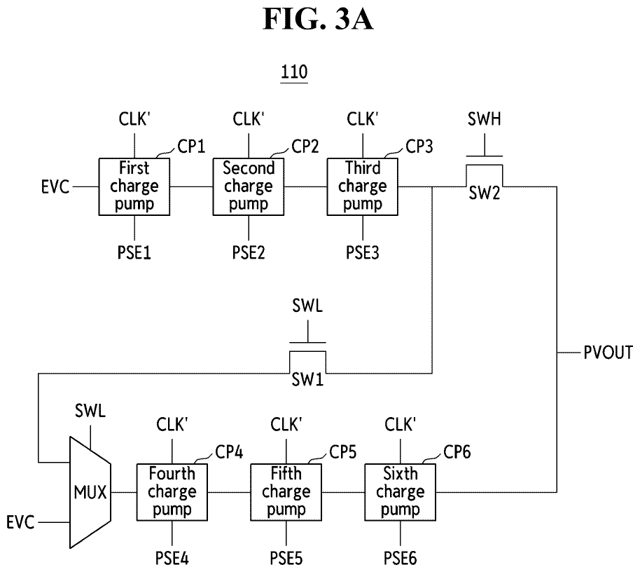

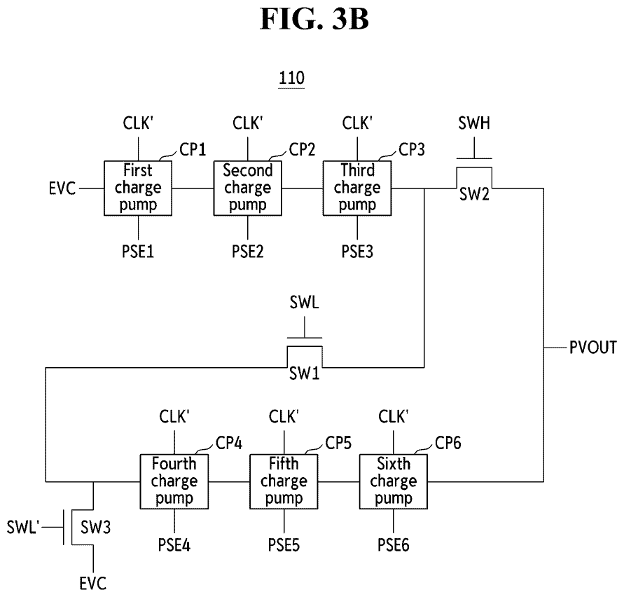

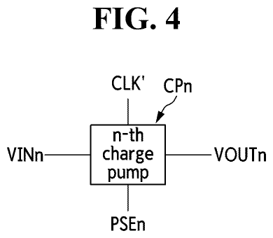

FIGS. 3A and 3B are circuit diagrams for illustrating a charge pump circuit of a memory device according to some embodiments of the present disclosure. FIG. 4 is a diagram illustrating the charge pump of FIG. 3A according to example embodiments.

Referring to FIG. 3A, the charge pump circuit 110 may include a plurality of charge pumps, a first switch SW1 and a second switch SW2, and a multiplexer circuit MUX. In an embodiment, each of the first and second switches SW1 and SW2 may include an N-type metal-oxide semiconductor (NMOS) transistor.

Referring to FIG. 3A, the charge pump circuit 110 may include first to sixth charge pumps CP1 to CP6. The first charge pump CP1 may receive a first enable signal PSE1 and a first input voltage, for example, the external voltage EVC, and output a voltage by performing a first pumping of the first input voltage. The second charge pump CP2 may receive a second enable signal PSE2 and the voltage output from the first charge pump CP1 as a second input voltage, and output a voltage by performing a second pumping of the second input voltage. The third charge pump CP3 may receive a third enable signal PSE3 and the voltage output from the second charge pump CP2 as a third input voltage, and output a voltage by performing a third pumping of the third input voltage. The fourth charge pump CP4 may receive a fourth enable signal PSE4 and the voltage output from the third charge pump CP3 as a fourth input voltage, and output a voltage by performing a fourth pumping of the fourth input voltage. The fifth charge pump CP5 may receive a fifth enable signal PSE5 and the voltage output from the fourth charge pump CP4 as a fifth input voltage, and output a voltage by performing a fifth pumping of the fifth input voltage. The sixth charge pump CP6 may receive a sixth enable signal PSE6 and the voltage output from the fifth charge pump CP5 as a sixth input voltage, and output a voltage as the pump output voltage PVOUT by performing a sixth pumping of the sixth input voltage.

For example, each of the first to sixth charge pumps CP1 to CP6 may pump a corresponding input voltage based on a clock signal CLK′ generated from the clock generator 130.

In an example embodiment, the charge pump circuit 110 may include a first charge pump circuit and a second charge pump circuit. For example, the first charge pump circuit may include first to third charge pumps CP1 to CP3, and the second charge pump circuit may include fourth to sixth charge pumps CP4 to CP6. For example, the second charge pump circuit may further include the multiplexer circuit MUX connected to the fourth charge pump CP4. Referring to FIG. 3A, the first to third charge pumps CP1 to CP3 are connected in series and the fourth to sixth charge pumps CP4 to CP6 are connected in series. The multiplexer circuit MUX and the first switch SW1 may be connected between the third charge pump CP3 and the fourth charge pump CP4. Although FIG. 3A illustrates that the charge pump circuit 110 includes six charge pumps CP1, CP2, CP3, CP4, CP5, and CP6, the charge pump circuit 110 may include at least seven charge pumps, and the present disclosure is not limited to the number of charge pumps illustrated.

Although FIG. 3A illustrates that the charge pump circuit 110 includes the multiplexer circuit MUX, in FIG. 3B, the charge pump circuit 110 may include a third switch SW3 instead of the multiplexer circuit MUX. In this case, the third switch SW3 (e.g., NMOS transistor) may be connected to the first switch SW1 and the fourth charge pump CP4, and may input a voltage (e.g., the external voltage EVC) to the fourth charge pump CP4 in response to a switch control signal.

Referring to FIG. 3B, the third switch SW3 may operate complementarily to the first switch SW1. An operation signal SWL′ for the third switch SW3 may be complementary to an operation signal SWL for the first switch SW1. For example, when the operation signal SWL for the first switch SW1 is a logic high level, the operation signal SWL′ for the third switch SW3 may be a logic low level.

Referring to FIG. 4, a charge pump CPn may receive an input voltage VINn and an enable signal PSEn from the charge pump controller 120 to pump the input voltage VINn. For example, when the enable signal PSEn is received at the charge pump CPn, the clock signal CLK′ from the clock generator 130 to the charge pump CPn. When the clock signal CLK′ is input to the charge pump CPn, the charge pump CPn may pump the input voltage VINn to output an output voltage VOUTn.

Referring again to FIG. 3A, the charge pump circuit 110 may include the first and second switches SW1 and SW2, and the multiplexer circuit MUX. Specifically, the multiplexer circuit MUX may receive a voltage from the first switch SW1 and the external voltage EVC and output one of the voltage from the first switch SW1 and the external voltage EVC in response to a mux control signal, for example, a first mode signal SWL. The first switch SW1 may include a first end connected to an output node of the third charge pump CP3 and a second end connected to a first input terminal of the multiplexer circuit MUX. The second switch SW2 may include a first end connected to the output node of the third charge pump CP3 and a second end connected to an output node of the sixth charge pump CP6. Although FIG. 3A illustrates that the charge pump circuit 110 includes the two switches SW1 and SW2, the present disclosure is not limited to the number or positions of switches.

The first and second switches SW1 and SW2 may determine a mode of the charge pump circuit 110. The charge pump circuit 110 may operate in a first mode RDL or a second mode RDH. For example, the charge pump circuit 110 may operate in the first mode RDL when the first switch SW1 is turned on in response to a first mode signal SWL having a logic high level and the second switch SW2 is turned off in response to a second mode signal SWH having a logic low level. For example, the charge pump circuit 110 may operate in the second mode RDH when the second switch SW2 is turned on in response to the second mode signal SWH having the logic high level and the first switch SW1 is turned off in response to the first mode signal SWL having the logic low level. Although not shown, when the second switch SW2 is turned on in the second mode RDH, the third switch SW3 connected to the first switch SW1 and the fourth charge pump CP4 may input the external voltage EVC to the fourth charge pump CP4. For example, a timing of turning on of the third switch SW3 may be the same as or later than a timing of turning on of the second switch SW2.

Moreover, the first and second switches SW1 and SW2 may reconfigure the stages of the charge pump circuit 110. The stages may correspond to the number of charge pumps that may be connected to each other and may operate in the connected manner to each other.

For example, when the first switch SW1 is turned on and the second switch SW2 is turned off, the voltage output from the third charge pump CP3 may be input to the fourth charge pump CP4 via the multiplexer circuit MUX. For example, in response to the mux control signal, for example, the first mode signal SWL, the multiplexer circuit MUX may select the voltage output from the third charge pump CP3 and input the selected voltage output from the third charge pump CP3 to the fourth charge pump CP4. For example, in the first mode RDL, six charge pumps from the first charge pump CP1 to the sixth charge pump CP6 may operate through the first switch SW1 turned on and the second switch SW2 turned off. Thus, when the 6 charge pumps may perform pumping operations consecutively, the configuration of the charge pump circuit may be 6 stages. For example, in the first mode RDL, the sixth charge pump CP6 may output the pump output voltage PVOUT on an output node of the sixth charge pump CP6.

For example, when the second switch SW2 is turned on and the first switch SW1 is turned off, the external voltage EVC may be input to the fourth charge pump CP4 via the multiplexer circuit MUX. For example, in response to the mux control signal, for example, the first mode signal SWL, the multiplexer circuit MUX may select the external voltage EVC and input the selected external voltage EVC to the fourth charge pump CP4. For example, in the second mode RDH, three charge pumps from the first charge pump CP1 to the third charge pump CP3 may perform pumping operations consecutively, and three charge pumps from the fourth charge pump CP4 to the sixth charge pump CP6 may perform pumping operations consecutively. For example, in the second mode RDH, the three charge pumps (e.g., CP1 to CP3 and CP4 to CP6) perform pumping operations consecutively through the second switch SW2 turned on and the first switch SW1 turned off. In this case, the configuration of the charge pump circuit may be 3 stages. For example, in the second mode RDH, the third charge pump CP3 may output a voltage as the pump output voltage PVOUT through the second switch SW2 turned on, and the sixth charge pump CP6 may output the pump output voltage PVOUT on the output node of the sixth charge pump CP6.

Referring back to FIG. 3A, when the operation mode of the charge pump circuit 110 has changed by the first and second switches SW1 and SW2, the multiplexer circuit MUX may apply selected one of an output voltage of a corresponding charge pump connected to the first switch and the external voltage EVC based on the determined mode to a corresponding charge pump connected to an output terminal of the multiplexer circuit MUX. Specifically, the multiplexer circuit MUX may receive the first mode signal SWL and the second mode signal SWH, and output a selected voltage based on the first and second mode signals SWL and SWH.

For example, when the output terminal of the multiplexer circuit MUX is connected to the fourth charge pump CP4, two inputs of the multiplexer circuit MUX may be the external voltage EVC and the output voltage of the third charge pump CP3. In the first mode RDL, the multiplexer circuit MUX may output the voltage output from the third charge pump CP3 in response to the first mode signal SWL having a logic high level. The voltage output from the third charge pump CP3 may be selected from the multiplexer circuit MUX and applied the selected voltage as an input voltage to the fourth charge pump CP4. In the second mode RDH, the multiplexer circuit MUX may output the external voltage EVC in response to the first mode signal SWL having a logic low level. The external voltage EVC output from the multiplexer circuit MUX may be applied as an input voltage to the fourth charge pump CP4. Although the output terminal of the multiplexer circuit MUX is illustrated as being connected to the fourth charge pump CP4, the present disclosure is not limited thereto, and the position and input/output of the multiplexer circuit may vary.

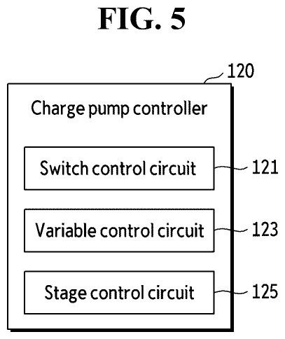

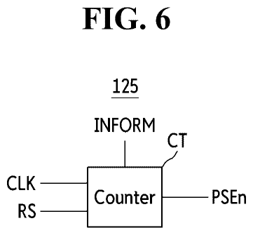

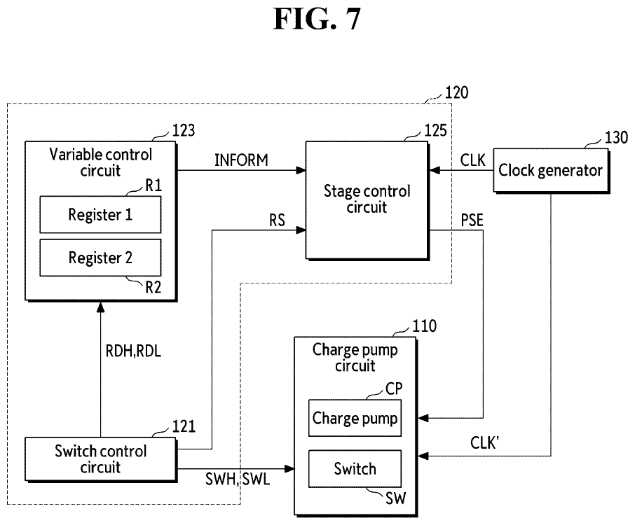

FIG. 5 is a block diagram for illustrating a charge pump controller of a memory device according to some embodiments of the present disclosure. FIG. 6 is a diagram illustrating a stage control circuit of FIG. 5 according to example embodiments. FIG. 7 is a block diagram for illustrating a voltage generator of a memory device according to some embodiments of the present disclosure.

Referring to FIG. 5 and FIG. 7, the charge pump controller 120 may include a switch control circuit 121, a variable control circuit 123, and a stage control circuit 125. The charge pump controller 120 may be included in the voltage generator 100 and may control the operation of the charge pump circuit 110. However, the present disclosure is not limited thereto. Moreover, the charge pump controller as described with reference to FIG. 5 to FIG. 7 is only one embodiment of implementing the present disclosure. However, the present disclosure is not limited thereto.

Referring to FIG. 5 and FIG. 7, the switch control circuit 121 may control the operation of the first and second switches SW1 and SW2 of the charge pump circuit 110. For example, the switch control circuit 121 may generate the first mode signal SWL that turns on the first switch SW1 of the charge pump circuit 110 and the second mode signal SWH that turns on the second switch SW2. The switch control circuit 121 may control the first and second switches SW1 and SW2 based on the first mode signal SWL and the second mode signal SWH.

The switch control circuit 121 may transmit the first mode signal SWL and second mode signal SWH to the variable control circuit 123. Moreover, when the mode is changed, the switch control circuit 121 may generate a mode reset signal RS.

Referring to FIG. 5 and FIG. 7, the variable control circuit 123 may control an operation timing of each of the charge pumps. Specifically, the variable control circuit 123 may determine information (INFORM) about the operation timing of each of the charge pumps and transmit the determined information to the stage control circuit 125. For example, the information may include information about the first and second mode signals SWL and SWH.

The variable control circuit 123 may include a register R1 and R2. The register R1 and R2 may store therein information that controls the timing of the enable signal PSE of each of the charge pump. Herein, the timing of the enable signal may mean an output timing or an enable timing of the enable signal. For example, the information stored in the register R1 and R2 may be information about a clock count value of a clock signal CLK received from the clock generator 130. The variable control circuit 123 is illustrated as including two registers. However, the present disclosure is not limited thereto.

The variable control circuit 123 may receive information about the mode of the charge pump circuit 110 from the switch control circuit 121. The variable control circuit 123 may determine an output value, based on the mode of the charge pump circuit 110. The information stored in the register R1 and R2 of the variable control circuit 123 may vary based on whether the operation mode is the first mode RDL or the second mode RDH. Specifically, the clock count value controlling the timing of the enable signal PSE of each charge pump stored in the register may vary based on whether the operation mode is the first mode RDL or the second mode RDH.

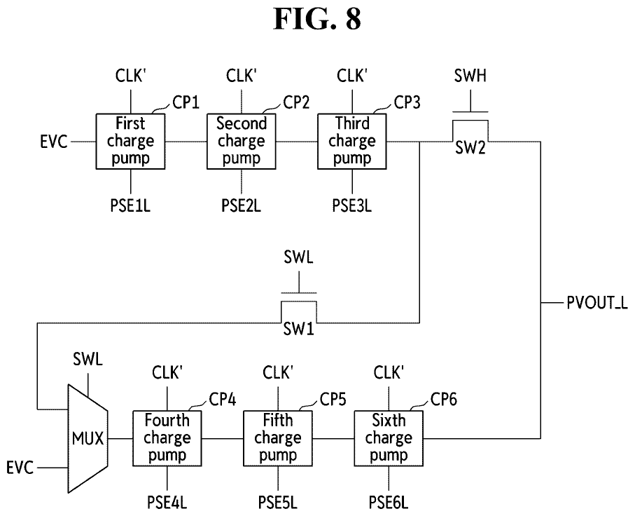

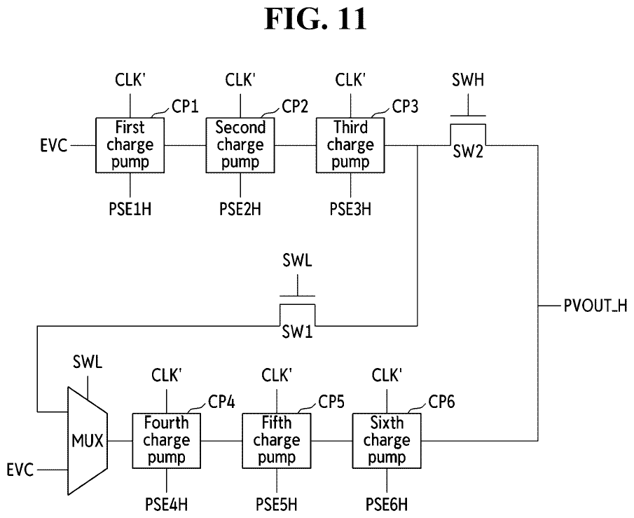

For example, in the first mode RDL, 6 stages may operate consecutively. Thus, the clock count value controlling the timing of an enable signal PSE3L (shown in FIG. 8) of the third charge pump CP3 may be greater than the clock count value controlling the timing of an enable signal PSE4L (shown in FIG. 8) of the fourth charge pump CP4. For example, in the second mode RDH, 3 stages may operate consecutively. Thus, the third charge pump CP3 and the fourth charge pump CP4 may operate independently as separate stages. Therefore, the clock count value controlling the timing of the enable signal PSE3H (shown in FIG. 11) of the third charge pump CP3 and the clock count value controlling the timing of the enable signal PSE4H (shown in FIG. 11) of the fourth charge pump CP4 may be determined independently of each other. The clock count value controlling the timing of the enable signal PSE3H of the third charge pump CP3 may be larger or smaller than the clock count value controlling the timing of the enable signal PSE4H of the fourth charge pump CP4.

Referring to FIG. 5 to FIG. 7, the stage control circuit 125 may output a plurality of enable signals PSE including the enable signal PSEn based on the clock signal CLK. The stage control circuit 125 may include a counter CT. The counter CT may output the enable signal PSEn based on information received from the register R1 and R2 of the variable control circuit 123. The enable signal PSEn output from the stage control circuit 125 may be input to the charge pump CPn of the charge pump circuit 110.

When the mode of the charge pump circuit 110 is changed, the stage control circuit 125 may receive the mode reset signal RS from the switch control circuit 121. When the stage control circuit 125 is received the mode reset signal RS, the stage control circuit 125 may reset the counter CT in response to the mode reset signal RS.

Specifically, the counter CT of the stage control circuit 125 may receive the clock signal CLK from the clock generator 130. Furthermore, the counter CT may receive information about the clock count value that controls the timing of the enable signal of the charge pump CPn from the register R1 and R2 of the variable control circuit 123. The stage control circuit 125 may control the timing of the enable signal according to the clock signal CLK, based on the information about the clock count value. However, this is only one of the embodiments for implementing the present disclosure. However, the present disclosure is not limited thereto.

For example, when the charge pump circuit 110 operates in the first mode RDL, the counter CT of the stage control circuit 125 may receive information of the register that stored therein information about the enable signal timing in the first mode RDL from the variable control circuit 123. Therefore, the counter CT may output an enable signal PSEnL (shown in FIG. 8) based on the clock count value stored in the register in the first mode RDL.

Thereafter, when the charge pump circuit 110 has been changed from the first mode RDL to the second mode RDH, the counter CT may receive the mode reset signal RS from the switch control circuit 121. When the counter CT is received the mode reset signal RS, the information stored in the counter CT is reset.

Afterwards, when the charge pump circuit 110 operates in the second mode RDH, the reset counter CT may receive information of the register storing therein information about the enable signal timing in the second mode RDH from the variable control circuit 123. Therefore, the counter CT may output the enable signal PSEnH (shown in FIG. 11) based on the clock count value stored in the register in the second mode RDH.

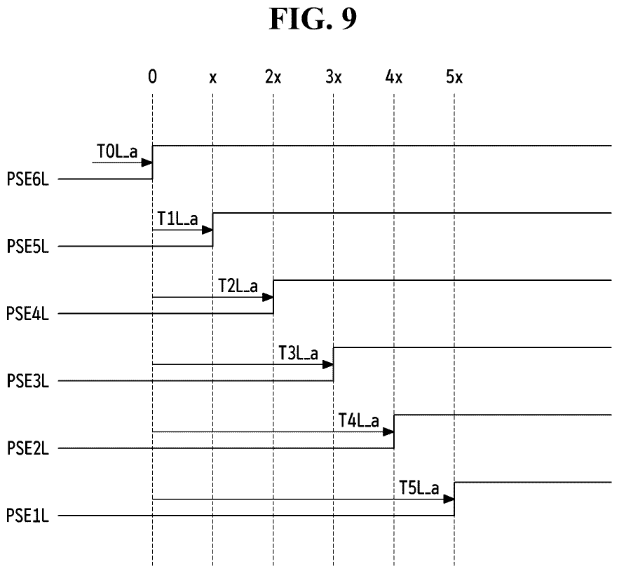

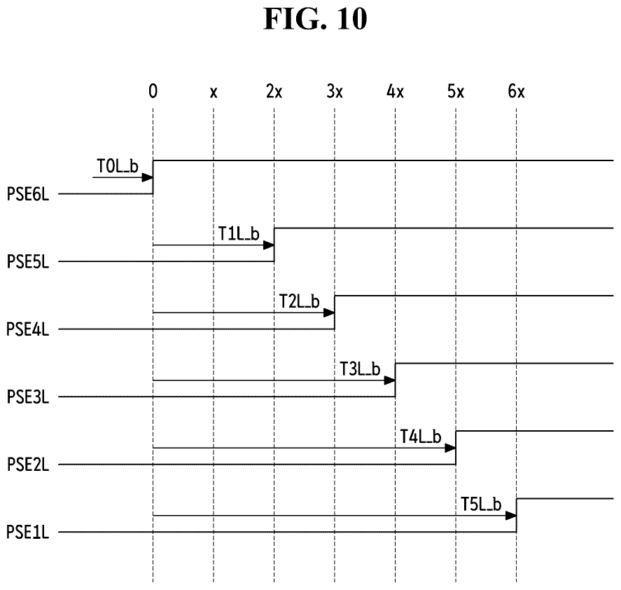

FIG. 8 is a circuit diagram for illustrating the first mode of the charge pump circuit of the memory device according to some embodiments of the present disclosure. FIG. 9 is a timing diagram for illustrating the first mode of FIG. 8 according to example embodiments. FIG. 10 is another timing diagram for illustrating the first mode of FIG. 8 according to example embodiments.

Referring to FIGS. 8 to 10, the charge pump circuit 110 operates in the first mode RDL in which the first switch SW1 is turned on and the second switch SW2 is turned off.

The first switch SW1 of the charge pump circuit 110 may receive the first mode signal SWL that turns on the first switch SW1 from the switch control circuit 121. Thereafter, as the first switch SW1 has been turned on, each charge pump may receive the enable signal PSEnL according to the first mode RDL from the charge pump controller 120. It is assumed that the register storing therein information that controls the timing of the enable signal PSEnL according to the first mode RDL is the first register R1.

Specifically, the first to sixth charge pumps CP1, CP2, CP3, CP4, CP5, and CP6 may respectively receive first to sixth enable signals PSEIL, PSE2L, PSE3L, PSE4L, PSE5L, and PSE6L based on the information stored in the first register R1. When the first to sixth enable signals PSEIL, PSE2L, PSE3L, PSE4L, PSE5L, and PSE6L are respectively input to the first to sixth charge pumps CP1, CP2, CP3, CP4, CP5, and CP6, the clock signal CLK′ from the clock generator 130 may be input to the first to sixth charge pumps CP1, CP2, CP3, CP4, CP5, and CP6. Each of the first to sixth charge pumps CP1, CP2, CP3, CP4, CP5, and CP6 may pump an input voltage and output a pumping voltage when a corresponding one of the first to sixth enable signals PSEIL, PSE2L, PSE3L, PSE4L, PSE5L, and PSE6L is enabled based on the clock signal CLK′.

When the charge pump circuit 110 operates in the first mode RDL, a time when the sixth enable signal PSE6L is input to the sixth charge pump CP6 is defined as a zero-th time-point TOL_a. In the first mode RDL, a time when the n-th enable signal PSEnL is input to the n-th charge pump CPn may be defined as an m-th time-point TmL_a that is later by an n-th time than the zero-th time-point TOL_a, where each of m and n may be one of the numbers from 1 to 5.

For example, in the first mode RDL, a time when the fifth enable signal PSE5L is input to the fifth charge pump CP5 may be determined as a fifth time-point TIL_a that is later by a fifth time x than the zero-th time-point TOL_a. In the first mode RDL, a time when the fourth enable signal PSE4L is input to the fourth charge pump CP4 may be determined as a fourth time-point T2L_a that is later by a fourth time 2× than the zero-th time-point TOL_a. In the first mode RDL, a time when the third enable signal PSE3L is input to the third charge pump CP3 may be determined as a third time-point T3L_a that is later by a third time 3× than the zero-th time-point TOL_a. In the first mode RDL, a time when the second enable signal PSE2L is input to the second charge pump CP2 may be determined as a second time-point T4L_a that is later by a second time 4× than the zero-th time-point TOL_a. In the first mode RDL, a time when the first enable signal PSEIL is input to the first charge pump CP1 may be determined as a first time-point T5L_a that is later by a first time 5× than the zero-th time-point TOL_a. In example embodiments, each of the first to fifth time x to 5× may correspond to a clock count value of the clock signal CLK. For example, the fifth time x may correspond to 2 clocks, the fourth time 2× may correspond to 4 clocks, and the third time 3× may correspond to 6 clocks. For other examples, the fifth time x may correspond to 5 clocks, the fourth time 2× may correspond to 7 clocks, and the third time 3× may correspond to 10 clocks.

An enable timing of each of the first to fifth charge pumps CP5 after the zero-th time-point TOL_a as the enable timing of the sixth charge pump CP6 may be determined based on the information stored in the first register R1. Therefore, the charge pump controller 120 of the memory device according to the present disclosure may independently set the enable timing of each of the first to fifth charge pumps CP1 to CP5, based on the enable timing of the sixth charge pump CP6.

Referring again to FIG. 9, when the charge pump circuit 110 operates in the first mode RDL, the first register R1 may further include information about the clock count value that determines the enable timing TmL_a of the charge pump CPn.

For example, the clock count value that determines the enable timing TIL_a of the fifth charge pump CP5 may be x stored in the first register R1. The clock count value that determines the enable timing T2L_a of the fourth charge pump CP4 may be 2× stored in the first register R1. The clock count value that determines the enable timing T3L_a of the third charge pump CP3 may be 3× stored in the first register R1. The clock count value that determines the enable timing T4L_a of the second charge pump CP2 may be 4× stored in the first register R1. The clock count value that determines the enable timing T5L_a of the first charge pump CP1 may be 5× stored in the first register R1.

Referring to FIG. 10, an enable timing TmL_b of the charge pump CPn may be changed by changing the clock count value stored in the first register R1. Specifically, when the clock count value stored in the register is incremented by one, the enable timing of the charge pump may change.

When the charge pump circuit 110 operates in the first mode RDL, a time when the sixth enable signal PSE6L is input to the sixth charge pump CP6 is defined as a zero-th time-point TOL_b. In the first mode RDL, a time when the n-th enable signal PSEnL is input to the n-th charge pump CPn may be defined as an m-th time-point TmL_a that is later by an n-th time than the zero-th time-point TOL_b, where each of m and n may be one of the numbers from 1 to 5. Herein, the m-th time-point TmL_a may be referred to as an enabling time of the n-th enable signal PSEnL.

For example, in the first mode RDL, a time when the fifth enable signal PSE5L is input to the fifth charge pump CP5 may be determined as a fifth time-point TIL_b that is later by a fifth time x than the zero-th time-point TOL_b. In the first mode RDL, a time when the fourth enable signal PSE4L is input to the fourth charge pump CP4 may be determined as a fourth time-point T2L_b that is later by a fourth time 2× than the zero-th time-point TOL_b. In the first mode RDL, a time when the third enable signal PSE3L is input to the third charge pump CP3 may be determined as a third time-point T3L_b that is later by a third time 3× than the zero-th time-point TOL_b. In the first mode RDL, a time when the second enable signal PSE2L is input to the second charge pump CP2 may be determined as a second time-point T4L_b that is later by a second time 4× than the zero-th time-point TOL_b. In the first mode RDL, a time when the first enable signal PSEIL is input to the first charge pump CP1 may be determined as a first time-point T5L_b that is later by a first time 5× than the zero-th time-point TOL_b.

For example, when each of all of the clock count values stored in the first register R1 is incremented by one, the clock count value that determines the enable timing TIL_b of the fifth charge pump CP5 may be 2×. The clock count value that determines the enable timing T2L_b of the fourth charge pump CP4 may be 3×. The clock count value that determines the enable timing T3L_b of the third charge pump CP3 may be 4×. The clock count value that determines the enable timing T4L_b of the second charge pump CP2 may be 5×. The clock count value that determines the enable timing T5L_b of the first charge pump CP1 may be 6×.

The charge pump controller 120 of the memory device according to the present disclosure may be configured to independently set the enable timing of each of the first to fifth charge pumps CP1, CP2, CP3, CP4, and CP5 based on the time-point TOL_a or TOL_b at which the sixth charge pump CP6 is enabled, based on the clock count value.

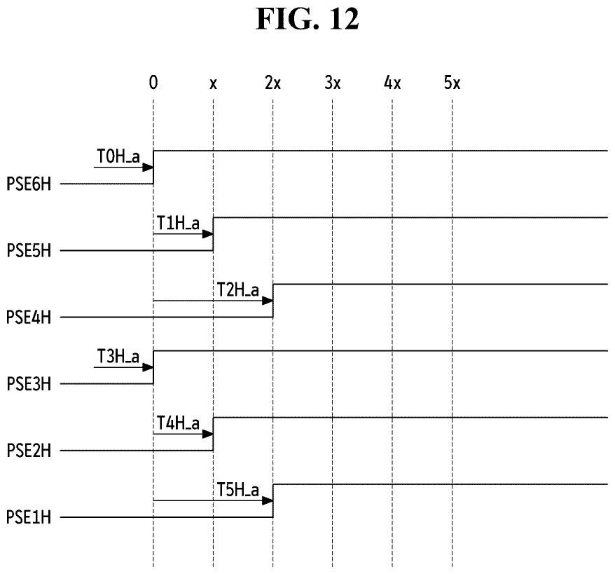

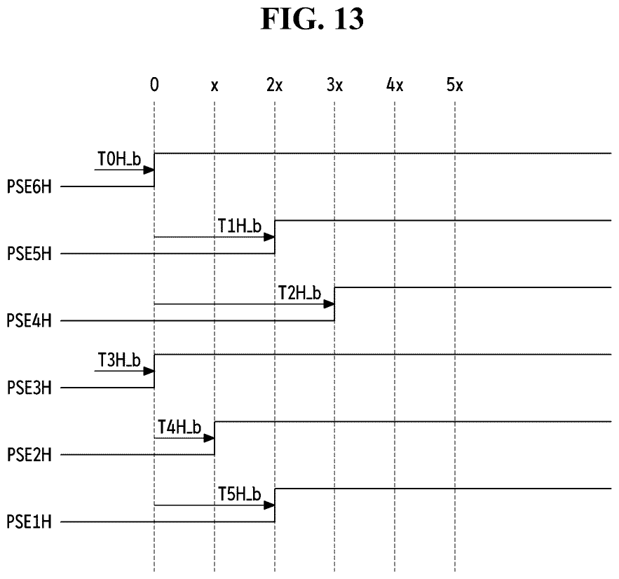

FIG. 11 is a circuit diagram for illustrating the second mode of the charge pump circuit of the memory device according to some embodiments of the present disclosure. FIG. 12 is a timing diagram for illustrating the second mode of FIG. 11 according to example embodiments. FIG. 13 is another timing diagram for illustrating the second mode of FIG. 11 according to example embodiments.

Referring to FIGS. 11 to 13, the charge pump circuit 110 operates in the second mode RDH in which the second switch SW2 is turned on and the first switch is turned off.

The second switch SW2 of the charge pump circuit 110 may receive the second mode signal SWH that turns on the second switch SW2 from the switch control circuit 121. Afterwards, as the second switch SW2 is turned on, each charge pump may receive an enable signal PSEnH according to the second mode RDH from the charge pump controller 120. It is assumed that the register storing therein information controlling the timing of the enable signal PSEnH according to the second mode RDH is the second register R2.

Specifically, the first to sixth charge pumps CP1, CP2, CP3, CP4, CP5, and CP6 may respectively receive first to sixth enable signals PSE1H, PSE2H, PSE3H, PSE4H, PSE5H, and PSE6H based on the information stored in the second register R2. When the first to sixth enable signals PSE1H, PSE2H, PSE3H, PSE4H, PSE5H, and PSE6H are respectively input to the first to sixth charge pumps CP1, CP2, CP3, CP4, CP5, and CP6, the clock signal CLK′ from the clock generator 130 may be input to the first to sixth charge pumps CP1, CP2, CP3, CP4, CP5, and CP6. Each of the first to sixth charge pumps CP1, CP2, CP3, CP4, CP5, and CP6 may pump an input voltage and output a pumping voltage when a corresponding one of the first to sixth enable signals PSE1H, PSE2H, PSE3H, PSE4H, PSE5H, and PSE6H is enabled based on the clock signal CLK′

When the charge pump circuit 110 operates in the second mode RDH, a time when the sixth enable signal PSE6H is input to the sixth charge pump CP6 is defined as a zero-th time-point T0H_a. In the second mode RDH, a time when the n-th enable signal PSEnH is input to the n-th charge pump CPn may be defined as a m-th time-point TmH_a which is later by an n-th time than the zero-th time-point T0H_a, where each of m and n may be 4 or 5.

For example, in the second mode RDH, a time when the fifth enable signal PSE5H is input to the fifth charge pump CP5 may be defined as a fifth time-point TIH_a that is later by a fifth time x than the zero-th time-point T0H_a. In the second mode RDH, a time when the fourth enable signal PSE4H is input to the fourth charge pump CP4 may be defined as a fourth time-point T2H_a that is later by a fourth time 2× than the zero-th time-point T0H_a.

When the charge pump circuit 110 operates in the second mode RDH, a time when the third enable signal PSE3H is input to the third charge pump CP3 may be defined as a third time-point T3H_a. In the second mode RDH, a time when the n-th enable signal PSEnH is input to the n-th charge pump CPn may be defined as an m-th time-point TmH_a that is later by an n-th time than the third time-point T3H_a, where each of m and n may be 1 or 2.

For example, in the second mode RDH, a time when the second enable signal PSE2H is input to the second charge pump CP2 may be defined as a second time-point T4H_a that is later by the fifth time x than the third time-point T3H_a. In the second mode RDH, a time when the first enable signal PSE1H is input to the first charge pump CP1 may be defined as a first time-point T5H_a that is later by the fourth time 2× than the third time-point T3H_a.

In the second mode RDH, the zero-th time-point T0H_a at which the sixth enable signal PSE6H is input to the sixth charge pump CP6 and the third time-point T3H_a at which the third enable signal PSE3H is input to the third charge pump CP3 may be independent of each other. The zero-th time-point T0H_a and the third time-point T3H_a may be the same as or different from each other. For example, the third time-point T3H_a may be later than the zero-th time-point T0H_a.

Therefore, the charge pump controller 120 of the memory device according to the present disclosure may independently set the operation timing of each of the first and second charge pump CP1 and CP2 based on the time-point at which the third charge pump CP3 is enabled. Furthermore, the charge pump controller 120 of the memory device according to the present disclosure may independently set the operation timing of each of the fourth and fifth charge pump CP4 and CP5 based on the time-point at which the sixth charge pump CP6 is enabled.

Referring again to FIG. 12, when the charge pump circuit 110 operates in the second mode RDH, the second register R2 may further include information about the clock count value that determines the enable timing TmH_a of the charge pump CPn.

For example, the clock count value that determines the enable timing TIH_a of the fifth charge pump CP5 may be x stored in the second register R2. The clock count value that determines the enable timing T2H_a of the fourth charge pump CP4 may be 2× stored in the second register R2. The clock count value that determines the enable timing T4H_a of the second charge pump CP2 may be x stored in the second register R2. The clock count value that determines the enable timing T5H_a of the first charge pump CP1 may be 2× stored in the second register R2. The enable timing of the charge pump may be determined based on the clock count value stored in the register.

Referring to FIG. 13, the enable timing of the charge pump may be determined based on the clock count value stored in the register. For example, when the clock count values of the fourth and fifth charge pumps CP4 and CP5 stored in the second register R2 are incremented by one, the clock count value that determines an enable timing TIH_b of the fifth charge pump CP5 may be 2×. The clock count value that determines the enable timing T2H_b of the fourth charge pump CP4 may be 3×. When the clock count values of the first and second charge pumps CP1 and CP2 are not changed, the clock count value that determines the enable timing T4H_b of the second charge pump CP2 may be 1×. The clock count value that determines the enable timing T5H_b of the first charge pump CP1 may be 2×.

In the second mode RDH, a first circuit composed of the first to third charge pumps CP1, CP2, and CP3 and a second circuit composed of the fourth to sixth charge pumps CP4, CP5, and CP6 may operate independently of each other. When the charge pump circuit 110 operates in the second mode RDH, the two circuits, each composed of the three stages, may operate independently of each other and may operate simultaneously in a parallel manner to each other.

Those as described above in the present disclosure with reference to FIG. 2 to FIG. 13 are only examples, and the present disclosure may be implemented in a different scheme.

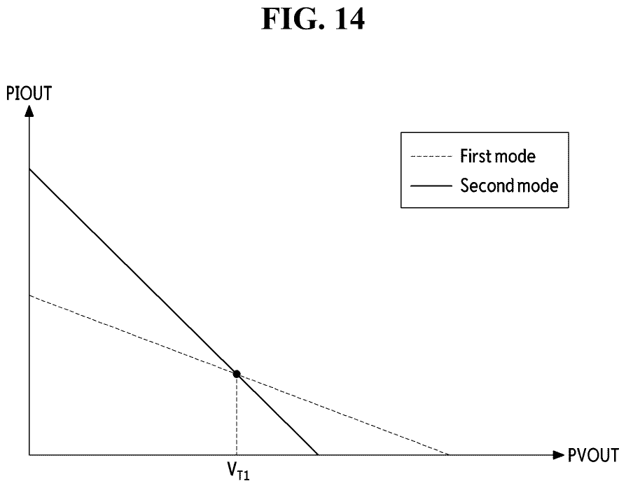

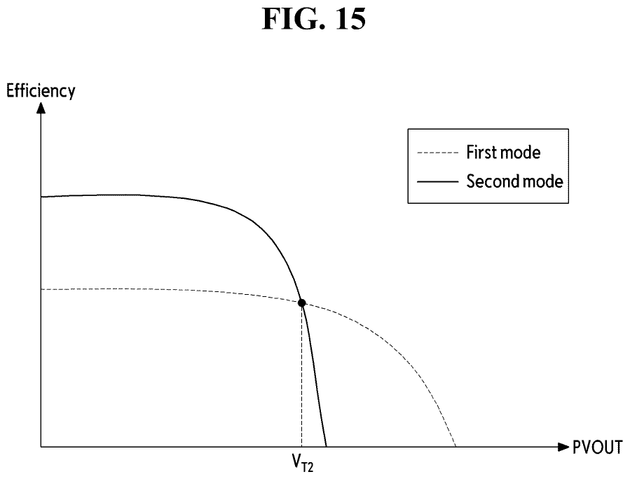

FIG. 14 is a graph of output voltage versus output current of the charge pump circuit of the memory device according to some embodiments of the present disclosure. FIG. 15 is a graph of output voltage versus efficiency of the charge pump circuit of the memory device according to some embodiments of the present disclosure.

Referring to FIG. 14, the graph of output voltage versus output current of the charge pump circuit 110 in each of the first mode RDL and the second mode RDH is illustrated. In the graph of FIG. 14, a horizontal axis represents the pump output voltage PVOUT and a vertical axis represents a pump output current PIOUT of the charge pump circuit. When generating the same pump output voltage, in the second mode RDH in which the first and second circuits are connected in parallel to each other, and each circuit of the first and second circuits is composed of 3 stages operating consecutively, a higher pump output current may be generated, compared to the first mode in which the 6 stages operate consecutively. Therefore, in order to obtain a pump output voltage lower than or equal to a first switching voltage V_{T1}, it may be more efficient for the charge pump circuit 110 to operate according to the second mode RDH than according to the first mode RDL. Specifically, when the charge pump circuit 110 operates according to the second mode RDH, the pump output voltage in a range below the first switching voltage V_{T1} may be achieved more quickly. Thus, the performance of the memory device may be improved when the charge pump circuit 110 operates in the second mode RDH.

However, in order to obtain a pump output voltage higher than the first switching voltage V_{T1}, that is, a high pump output voltage, a large number of stages may be needed. Thus, it may be more efficient for the charge pump circuit 110 to operate according to the first mode RDL to obtain the pump output voltage higher than the first switching voltage V_{T1}. For example, when the 6 stages operate consecutively according to the first mode, the peak current of the charge pump circuit may be reduced. Therefore, according to the present disclosure, the first mode signal SWL and the second mode signal SWH may be selectively applied based on whether the pump output voltage is below the first switching voltage V_{T1}, thereby further improving the power efficiency.

Referring to FIG. 15, the graph of output voltage versus efficiency according to each of the first mode RDL and the second mode RDH of the charge pump circuit 110 is shown. In the graph of FIG. 15, a horizontal axis represents the pump output voltage PVOUT and a vertical axis represents an efficiency of the charge pump circuit. The pump output current of the same intensity as that in the first mode RDL in which the 6 stages operate consecutively may be generated in the second mode RDH in which the two circuits are connected in parallel to each other, and each circuit is composed of 3 stages operating consecutively. Thus, the second mode RDH may be more efficient when the pump output voltage is lower than or equal to a second switching voltage V_{T2}. Specifically, when the charge pump circuit 110 operates according to the second mode RDH, the pump output voltage in a range below the second switching voltage V_{T2} may be achieved more quickly. Thus, the performance of the memory device may be improved when the charge pump circuit 110 operates in the second mode RDH.

Alternatively, in order to obtain the pump output voltage higher than the second switching voltage V_{T2}, that is, a high pump output voltage, a large number of stages are useful. Thus, in this case, the first mode RDL in which the 6 stages operate consecutively may be more efficient.

The voltage generator 100 of the memory device 10 according to the present disclosure may be configured to control the first and second switches SW1 and SW2 of the charge pump circuit 110 to change the stage configuration of the charge pump circuit 110, and to control the stage enable timing such that the pump output voltage PVOUT may be achieved more quickly, and a large amount of peak current may be prevented from being generated. Furthermore, the memory device 10 may include the charge pump controller 120 that independently controls the enable timing to reduce a size of the voltage generator 100 in the memory device 10.

The voltage generator 100 of the memory device 10 may be configured to change the configuration of the charge pump circuit 110, and sense the output pump current and to control the stage of the charge pump circuit 110 based on the sensing result, so that unnecessary power consumption when performing an operation may be reduced, and an operation speed may be increased.

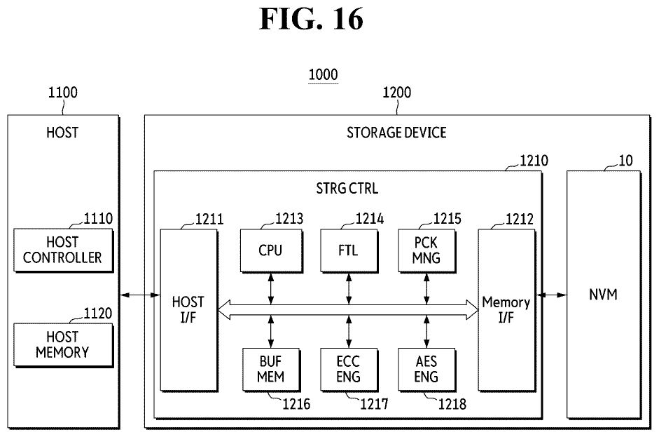

FIG. 16 is a block diagram of an SSD system including a memory device according to some embodiments of the present disclosure.

Referring to FIG. 16, an SSD system 1000 may include a host 1100 and an SSD or a storage device 1200. The SSD 1200 may exchange signals with the host 1100 through a signal connector and may receive power through a power connector. The SSD 1200 may include an SSD controller 1210 and a memory device 10. The SSD 1200 may be implemented using the embodiments as described above with reference to FIG. 1 to FIG. 13. The memory device 10 of FIG. 16 may be the memory device 10 described above with reference to FIG. 1. The memory device 10 of FIG. 16 may include one or more memory devices. Each of the memory devices 10 may include a charge pump circuit and a stage controller that controls a stage of the charge pump circuit. Accordingly, when performing an operation (e.g., one of a program operation, a read operation, and an erase operation), the SSD system may reduce unnecessary power consumption or increase an operation speed depending on a magnitude of the pump output current.

While the inventive concept has been particularly shown and described with reference to embodiments thereof, it will be understood that various changes in form and details may be made therein without departing from the spirit and scope of the present invention as set forth in the following claims.

What is claimed is:

1. A memory device comprising:
a memory cell array including a plurality of memory cells;
a voltage generator configured to generate an output voltage and provide the output voltage to the memory cell array,
wherein the voltage generator comprises:
a clock generator configured to generate a clock signal;
a charge pump controller configured to generate a plurality of enable signals based on the clock signal;
a first charge pump circuit configured to pump a first voltage and output a first pumping voltage;
a second charge pump circuit configured to pump the first pumping voltage or the first voltage and output a second pumping voltage as the output voltage; and
first and second switches connected between the first charge pump circuit and the second charge pump circuit,
wherein the charge pump controller is configured to respectively enable the first and second charge pump circuits in response to the plurality of enable signals, and
wherein each the plurality of enable signals is independently set an output timing from a first time-point at which the earliest enabled signal from among the plurality of enable signals is output.

2. The memory device of claim 1, wherein the first charge pump circuit and the second charge pump circuit are connected in parallel to each other in response to the second switch being turned on.

3. The memory device of claim 1, wherein the first charge pump circuit comprises:
a first charge pump configured to pump the first voltage and output a first output voltage based on a first enable signal among the plurality of enable signals; and
a second charge pump connected to the first charge pump and configured to pump the first output voltage and output a second output voltage as the first pumping voltage based on a second enable signal among the plurality of enable signals, and
wherein the second enable signal and the first enable signal are sequentially output.

4. The memory device of claim 3, wherein the first charge pump circuit further comprises:
a third charge pump connected between the second charge pump and the first switch and configured to pump the second output voltage and output a third output voltage as the first pumping voltage based on a third enable signal among the plurality of enable signals, and
wherein the third enable signal is output before outputting the first and second enable signals.

5. The memory device of claim 4, wherein the charge pump controller is configured to independently set an output timing of each of the first to third enable signals from the first time-point.

6. The memory device of claim 4, further comprising:
a third switch connected to the first switch,
wherein the second charge pump circuit comprises:
a fourth charge pump connected to the first switch and configured to pump the third output voltage and output a fourth output voltage based on a fourth enable signal among the plurality of enable signals; and
a fifth charge pump connected between the second switch and the fourth charge pump and configured to pump the fourth output voltage and output a fifth output voltage as the second pumping voltage based on a fifth enable signal among the plurality of enable signals,
wherein the fifth enable signal and the fourth enable signal are sequentially output, and
wherein the third switch is connected to the fourth charge pump and configured to input the first voltage to the fourth charge pump in response to the third switch being turned on.

7. The memory device of claim 6, wherein when the first switch is turned on, the charge pump controller is configured to sequentially output the fourth enable signal and the third enable signal.

8. The memory device of claim 6, wherein when the second switch is turned on, the charge pump controller is configured to independently output the third enable signal and the fifth enable signal.

9. The memory device of claim 6, wherein the charge pump controller is configured to:
independently set an output timing of each of the first to third enable signals from the first time-point, and
independently set an output timing of each of the fourth and fifth enable signals from a second time-point.

10. The memory device of claim 9, wherein when the first switch is turned on, the first time-point and the second time-point are different from each other, and
wherein when the second switch is turned on, the first time-point is the same as the second time-point.

11. A memory device comprising:
a memory cell array including a plurality of memory cells; and
a voltage generator configured to generate an output voltage and provide the output voltage to the memory cell array,
wherein the voltage generator comprises:
a first charge pump configured to perform a first-pumping of a first voltage and output a first output voltage based on a first enable signal;
a second charge pump configured to perform a second-pumping of the first output voltage and output a second output voltage based on a second enable signal;
a third charge pump configured to perform a third-pumping of a second voltage and output a third output voltage based on a third enable signal;
a fourth charge pump configured to perform a fourth-pumping of the third output voltage and output a fourth output voltage as the output voltage based on a fourth enable signal;
a first switch connected between the second charge pump and the third charge pump;
a second switch connected between the second charge pump and the fourth charge pump; and
a charge pump controller configured to generate the first to fourth enable signals in response to the first and second switches being turned on or turned off,
wherein the voltage generator is configured to operate:
in a first mode in which the first switch is turned on and the second switch is turned off, and
in a second mode in which the first switch is turned off and the second switch is turned on, and
wherein a first time-point at which the second enable signal is enabled is earlier than a second time-point at which the third enable signal is enabled.

12. The memory device of claim 11, wherein in the second mode of the voltage generator, the first time-point at which the second enable signal is enabled is the same as a third time-point at which the fourth enable signal is enabled.

13. The memory device of claim 11, wherein in the second mode of the voltage generator, a fourth time-point at which the first enable signal is enabled is independent of the second time-point at which the third enable signal is enabled.

14. The memory device of claim 11, wherein the voltage generator further comprises:
a fifth charge pump connected between the first charge pump and configured to perform a fifth-pumping of a fourth voltage and output the first voltage based on a fifth enable signal, and
wherein in the second mode of the voltage generator, a third time-point at which the fifth enable signal is enabled is later than a fourth time-point at which the first enable signal is enabled, and is independent of the second time-point at which the third enable signal is enabled.

15. The memory device of claim 11, wherein the charge pump controller is configured to sequentially output the second enable signal and the first enable signal, and to sequentially output the fourth enable signal and the third enable signal.

16. The memory device of claim 11, wherein in the first mode of the voltage generator, the charge pump controller is configured to sequentially output the fourth enable signal, the third enable signal, the second enable signal, and the first enable signal.

17. The memory device of claim 11, wherein in the second mode of the voltage generator, the charge pump controller is configured to:
individually set an output timing of each of the first and second enable signals from a third time-point, and
individually set an output timing of each of the third and fourth enable signals from a fourth time-point.

18. The memory device of claim 17, wherein in the first mode of the voltage generator, the third time-point and the fourth time-point are different from each other, and
wherein in the second mode of the voltage generator, the third time-point is the same as the fourth time-point.

19. A memory device comprising:
a memory cell array including a plurality of memory cells; and
a voltage generator configured to generate an output voltage and provide the output voltage to the memory cell array,
wherein the voltage generator comprises:
a first charge pump configured to perform a first-pumping of a first voltage and output a first output voltage based on a first enable signal;
a second charge pump configured to perform a second-pumping of the first output voltage based on a second enable signal;
a third charge pump configured to perform a third-pumping of a second voltage and output a third output voltage based on a third enable signal;
a fourth charge pump configured to perform a fourth-pumping of the third output voltage and output a fourth output voltage as the output voltage based on a fourth enable signal;
a first switch connected between the second charge pump and the third charge pump;
a second switch connected between the second charge pump and the fourth charge pump; and
a charge pump controller configured to generate the first to fourth enable signals in response to the first and second switches being turned on or turned off,
wherein, in response to the first switch being turned off and the second switch being turned on, the charge pump controller is configured to sequentially output the second enable signal and the first enable signal and to sequentially output the fourth enable signal and the third enable signal.

20. The memory device of claim 19, wherein an output timing of the second enable signal is earlier than an output timing of the third enable signal.
